(19) United States
(12) Patent Application Publication
(10) Pub. No.: US 2020/0053918 A1
(43) Pub. Date: Feb. 13, 2020

(54) HEAT SINK AND DISPLAY DEVICE INCLUDING THE SAME

(71) Applicant: Samsung Display Co., Ltd., Yongin-si (KR)

(72) Inventors: Tae Sung KIM, Yongin-si (KR); Ju Hee KIM, Yongin-si (KR)

(21) Appl. No.: 16/510,977

(22) Filed: Jul. 15, 2019

(30) Foreign Application Priority Data
Aug. 7, 2018 (KR) 10-2018-0091742

(51) Int. Cl. H05K 7/20; F21V 29/58; F21V 29/76

(52) U.S. Cl. CPC H05K 7/20954; F21V 29/76; F21V 29/59; H05K 7/2039

(57) ABSTRACT

A heat sink includes: a heat radiating plate in contact with a heat generation object; a plurality of heat radiating fins disposed on the heat radiating plate, the plurality of heat radiating fins forming sidewalls of a heat radiation path; a fluid guide disposed between the plurality of heat radiating fins, the fluid guide having a shape protruding from the heat radiating plate extending in a first direction; and a cooling fan having a rotation axis extending in the first direction, the rotation axis of the cooling fan corresponding to the fluid guide

### CROSS-REFERENCE TO RELATED APPLICATION

This application claims priority from and the benefit of Korean Patent Application No. 10-2018-0091742 filed on Aug. 7, 2018, which is hereby incorporated by reference for all purposes as if fully set forth herein.

### BACKGROUND

### Field

Exemplary embodiments/implementations of the invention relate generally to a heat sink and a display device including the same.

### Discussion of the Background

With the development of information technologies, the importance of a display device as a connection medium between a user and information has increased. Accordingly, display devices such as a liquid crystal display device, an organic light emitting display device, and a plasma display device are increasingly used.

In the case of a liquid crystal display device, lights are emitted from light sources, and a transmission amount of light is adjusted in each pixel of a display panel, so that an image frame can be displayed.

The light sources generate a large amount of heat while providing illumination. In particular, when light with high luminance is generated, the amount of heat generated from the light sources may increase. Therefore, the generated heat should be effectively radiated or dispersed such that the liquid crystal display device functions appropriately.

The above information disclosed in this Background section is only for understanding of the background of the inventive concepts, and, therefore, it may contain information that does not constitute prior art.

### SUMMARY

Devices constructed according to exemplary implementations of the invention provide a heat sink capable of effectively radiating or dispersing heat and a display device including the heat sink, which can realize a high-luminance display.

Additional features of the inventive concepts will be set forth in the description which follows, and in part will be apparent from the description, or may be learned by practice of the inventive concepts.

According to one or more embodiments of the invention, a heat sink includes: a heat radiating plate in contact with a heat generation object; a plurality of heat radiating fins disposed on the heat radiating plate, the plurality of heat radiating fins forming sidewalls of a heat radiation path; a fluid guide disposed between the plurality of heat radiating fins, the fluid guide having a shape protruding from the heat radiating plate extending in a first direction; and a cooling fan having a rotation axis extending in the first direction, the rotation axis of the cooling fan corresponding to the fluid guide.

The fluid guide may have a truncated conical shape in which an area of a first surface opposing the heat radiating plate is smaller than an area of a second surface facing the heat radiating plate.

A center of the first surface of the fluid guide and a center of the second surface of the fluid guide may be located a rotation axis of the cooling fan.

The fluid guide may have a conical shape.

The fluid guide may have a sectional area and the sectional area decreases with increasing distance away from the heat radiating plate.

The heat sink may further include a duct cover covering the plurality of heat radiating fins, to form an upper wall and an outlet of the heat radiation path, wherein the duct cover may include an inlet formed corresponding to the cooling fan.

According to one or more embodiments of the invention, a display device includes: a display panel including a plurality of pixels; a plurality of light sources configured to provide light to the plurality of pixels; a first heat radiating plate directly contacting a first group of light sources among the plurality of light sources; a plurality of first heat radiating fins disposed on one surface of the first heat radiating plate, the plurality of first heat radiating fins forming sidewalls of a first heat radiation path; a first fluid guide disposed between the plurality of first heat radiating fins, the first fluid guide having a shape protruding from the one surface of the first heat radiating plate in a first direction; and a first cooling fan having a rotation axis extending in the first direction, the rotation axis of the first cooling fan corresponding to the first fluid guide.

The display device may further include: a second heat radiating plate contacting a second group of light sources among the plurality of light sources; a plurality of second heat radiating fins disposed on one surface of the second heat radiating plate, the plurality of second heat radiating fins forming sidewalls of a second heat radiation path; a second fluid guide disposed between the plurality of second heat radiating fins, the second fluid guide having a shape protruding from the one surface of the second heat radiating plate in a second direction; and a second cooling fan having a rotation axis extending in the second direction, the rotation axis of the second cooling fan corresponding to the second fluid guide.

The display device may further include a bottom chassis supporting a second surface of the first heat radiating plate a second other surface of the second heat radiating plate.

The first heat radiating plate and the second heat radiating plate may be disposed on the bottom chassis to be spaced apart from each other.

According to one or more embodiments of the invention, a display device includes: a display panel including a plurality of pixels; a plurality of light sources configured to provide light to the plurality of pixels; a heat radiating plate contacting a first group of light sources among the plurality of light sources at a first side, and contacting a second group of light sources among the plurality of light sources at a second side, the second side being opposite to the first side; a plurality of heat radiating fins located on one surface of the heat radiating plate, the plurality of heat radiating fins forming sidewalls of a heat radiation path with respect to the plurality of light sources; a fluid guide having a shape protruding from the one surface of the heat radiating plate in a first direction; and a cooling fan having a rotation axis extending in the first direction, the rotation axis of the cooling fan corresponding to the fluid guide.

The display device may further include a duct cover covering the plurality of heat radiating fins, to form an upper wall and an outlet of the heat radiation path, wherein the duct cover may include an inlet formed corresponding to the cooling fan.

The display device may further include an auxiliary fin connected to at least some of the plurality of heat radiating fins, the heat radiating plate, and the duct cover, forming a fluidical connection between the heat radiation path and the inlet.

The auxiliary fin may extend from at least some of the plurality of heat radiating fins.

The auxiliary fin may extend from the duct cover.

The auxiliary fin may extend from the heat radiating plate.

The heat radiating plate may be contacting a third group of light sources among the plurality of light sources at a third side, the third side connecting the first side and the second side, and the heat radiating plate may be contacting a fourth group of light sources among the plurality of light sources at a fourth side, the fourth side being opposite to the third side.

An outermost heat radiating fin of the plurality of heat radiating fins may extend to surround the second side, the third side, and the fourth side. Both ends of the outermost heat radiating fin may be located at the first side, to form an outlet.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the inventive concepts.

FIG. 1 is a block diagram illustrating a display panel according to an exemplary embodiment.

FIG. 2 is a diagram illustrating a pixel according to an exemplary embodiment.

FIG. 3 is a cross-sectional diagram illustrating a display device according to an exemplary embodiment.

FIG. 4 is a fluid guide according to an exemplary embodiment.

FIG. 5 is a fluid guide according to another exemplary embodiment.

FIGS. 6, 7, and 8 are diagrams illustrating a cooling effect according to the length of a heat radiating plate.

FIGS. 9 and 10 are diagrams illustrating a heat sink according to a first embodiment.

FIG. 11 is a diagram illustrating a heat sink according to a second embodiment.

FIGS. 12 and 13 are diagrams illustrating a heat sink according to a third embodiment.

FIGS. 14 and 15 are diagrams illustrating a heat sink according to a fourth embodiment.

### DETAILED DESCRIPTION

In the following description, for the purposes of explanation, numerous specific details are set forth in order to provide a thorough understanding of various exemplary embodiments or implementations of the invention. As used herein “embodiments” and “implementations” are interchangeable words that are non-limiting examples of devices or methods employing one or more of the inventive concepts disclosed herein. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z-axes, and may be interpreted in a broader sense. For example, the X-axis, the Y-axis, and the Z-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

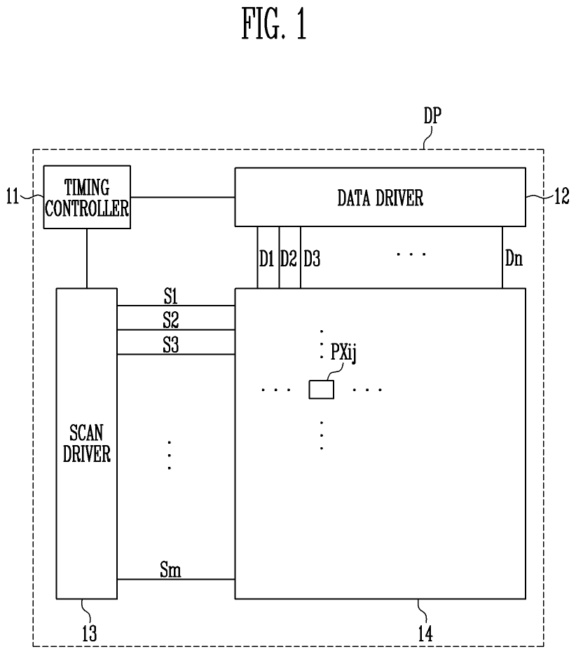

FIG. 1 is a block diagram illustrating a display panel according to an exemplary embodiment.

Referring to FIG. 1, the display panel DP may include a timing controller 11, a data driver 12, a scan driver 13, and a pixel unit 14.

The timing controller 11 may generate a clock signal, a scan start signal, etc. to be suitable for specifications of the scan driver 13, and provide the clock signal, the scan start signal, etc. to the scan driver 13. Also, the timing controller 11 may generate grayscale values, control signals, etc. to be suitable for specifications of the data driver 12, and provide the grayscale values, the control signals, etc. to the data driver 12.

The data driver 12 may generate data voltages to be provided to data lines D1, D2, D3, . . . , and Dn, using the grayscale values, the control signals, etc. For example, data voltages generated in units of pixel rows may be simultaneously applied to the data lines D1 to Dn in response to an output control signal included in a control signal.

The scan driver 13 may generate scan signals to be provided to scan lines S1, S2, S3, . . . , and Sm by receiving control signals including the clock signal, the scan start signal, etc. from the timing controller 11. The scan driver 13 may provide the scan signals through the scan lines S1 to Sm, to select at least some of pixels in which data voltages are to be written. For example, the scan driver 13 may sequentially provide the scan signals having a turn-on level to the scan lines S1 to Sm, to select a pixel row to which data voltages are to be written. The scan driver 13 may be configured in the form of a shift register, and generate the scan signals in a manner that sequentially transfers the scan start signal to a next stage circuit under the control of the clock signal.

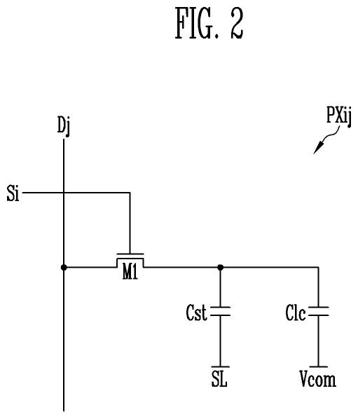

The pixel unit 14 includes pixels. Each pixel PXij may be connected to a corresponding data line and a corresponding scan line. For example, when data voltages for one pixel row are applied to the data lines D1 to Dn from the data driver 12, the data voltages may be written to a pixel row located at a scan line that receives a scan signal having the turn-on level from the scan driver 13. Such a driving method will be described in more detail with reference to FIG. 2.

FIG. 2 is a diagram illustrating a pixel according to an exemplary embodiment.

Referring to FIG. 2, the pixel PXij may include a transistor M1, a storage capacitor Cst, and a liquid crystal capacitor Clc.

In the current exemplary embodiment, the transistor M1 is illustrated as an N-type transistor, and therefore, the turn-on level of a scan signal may be a high level. Those skilled in the art may implement a pixel circuit performing the same function, using a P-type transistor.

A gate electrode of the transistor M1 may be connected to a scan line Si, one electrode of the transistor M1 may be connected to a data line Dj, and the other electrode of the transistor M1 may be connected to one electrode of the storage capacitor Cst and a pixel electrode of the liquid crystal capacitor Clc.

The one electrode of the storage capacitor Cst may be connected to the other electrode of the transistor M1, and the other electrode of the storage capacitor Cst may be connected to a sustain voltage line SL. In some exemplary embodiments, when the capacity of the liquid crystal capacitor Clc is sufficiently large, the configuration of the storage capacitor Cst may be excluded.

The pixel electrode of the liquid crystal capacitor Clc may be connected to the other electrode of the transistor M1, and a common voltage Vcom may be applied to a common electrode of the liquid crystal capacitor Clc.

When the scan signal having the turn-on level is supplied to the gate electrode of the transistor M1 through the scan line Si, the transistor M1 connect the data line Dj and the one electrode of the storage capacitor Cst. Therefore, a voltage corresponding to the difference between a data voltage applied through the data line Dj and a sustain voltage of the sustain voltage line SL is stored in the storage capacitor Cst. The data voltage is sustained at the pixel electrode of the liquid crystal capacitor Clc by the storage capacitor Cst. Thus, an electric field corresponding to the difference between the data voltage and the common voltage is applied to a liquid crystal layer, and the orientation of liquid crystal molecules of the liquid crystal layer is determined according to the electric field. The pixel PXij can emit light with a desired luminance while light of a backlight is passing through the liquid crystal molecules and a polarizing plate.

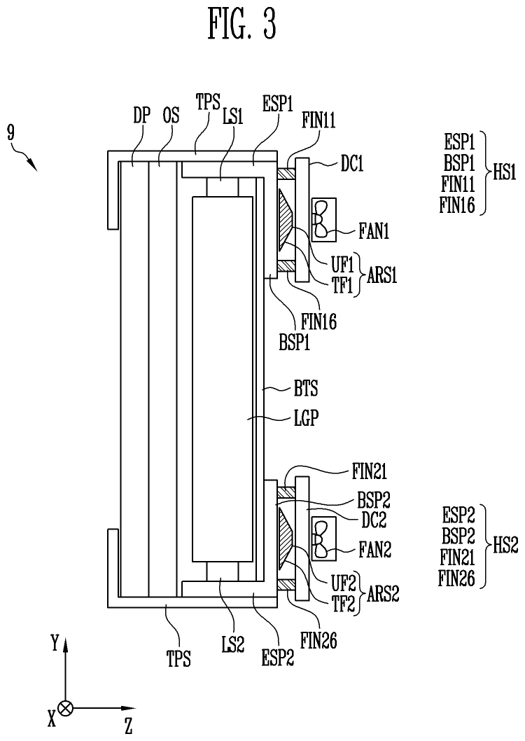

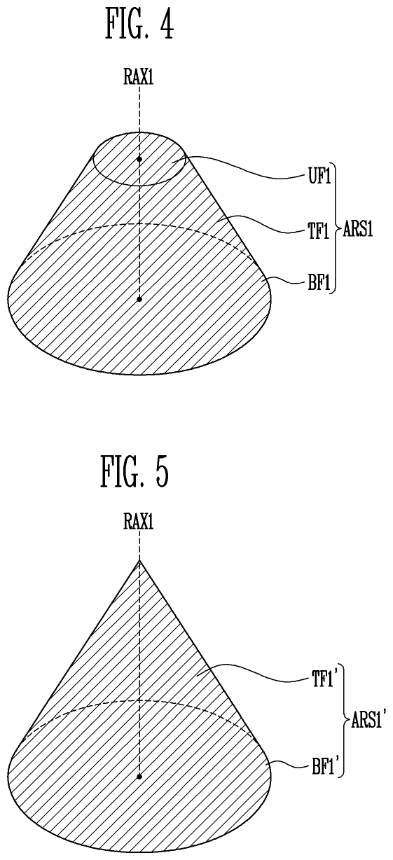

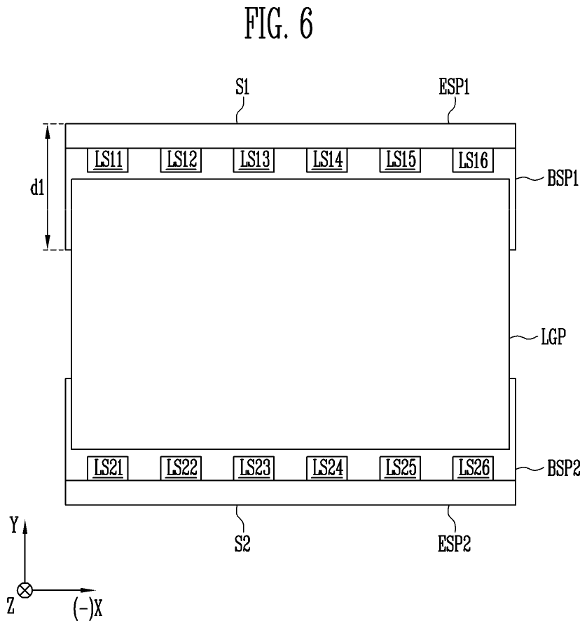

FIG. 3 is a cross-sectional diagram illustrating a display device according to an exemplary embodiment. FIG. 4 is a fluid guide according to an exemplary embodiment. FIG. 5 is a fluid guide according to another exemplary embodiment.

Referring to FIG. 3, the display device 9 according to the exemplary embodiment may include a display panel DP, light sources LS1 and LS2, heat radiating plates BSP1 and BSP2, heat radiating fins FIN11, FIN16, FIN21, and FIN26, fluid guides ARS1 and AR2, and cooling fans FAN1 and FAN2. In some exemplary embodiments, the display device 9 may selectively further include an optical sheet OS, a light guide plate LGP, a top chassis TPS, a bottom chassis BTS, duct covers DC1 and DC2, and the like.

Descriptions of the display panel DP refer to those of FIGS. 1 and 2. In addition, although not shown in the drawing, a polarizing plate may further located on one surface or both surfaces of the display panel DP.

The optical sheet OS may be located between the display panel DP and the light guide plate LGP. The optical sheet OS may enhance optical characteristics of light emitted from the light guide plate LGP. For example, the optical sheet OS may include at least one of a diffusion sheet, a prism sheet, and a reflective sheet. The diffusion sheet may improve uniformity of luminance and mixture efficiency of light by diffusing the light. The prism sheet may improve front luminance of light through reflection and refraction. The reflective sheet may improve luminance of light by reflecting the light toward the display panel DP.

The light guide plate LGP may be located between the optical sheet OS and the bottom chassis BTS. The light guide plate LGP may guide lights emitted from the light sources LS1 and LS2 and provide the light to the display panel DP.

The light sources LS1 and LS2 may be located between the light guide plate LGP and heat radiating structures HS1 and HS2. For example, the light sources LS1 and LS2 may be in contact with side protrusion parts ESP1 and ESP2 of the heat radiating plates BSP1 and BSP2, respectively. The light emission direction of the light sources LS1 and LS2 may face the light guide plate LGP. In the current exemplary embodiment, since the light sources LS1 and LS2 are located at sides of the light guide plate LGP, the light sources LS1 and LS2 constitute an edge type backlight structure. However, in another exemplary embodiment, the light sources LS1 and LS2 may be located on the bottom of the light guide plate LGP, so that the light emission direction of the light sources LS1 and LS2 and the light emission direction of the display device 9 are equal to each other.

The light sources LS1 and LS2 may correspond to at least one of a Light Emitting Diode (LED), a Cold Cathode Fluorescent Lamp (CCFL), an External Electrode Fluorescent Lamp (EEFL), a Flat Fluorescent Lamp (FFL), and the like. Hereinafter, for convenience of description, a case where the light sources LS1 and LS2 are LEDs are assumed and illustrated.

A heat sink may refer to an assembly of the heat radiating structure HS1, the fluid guide ARS1, the duct cover DC1, and a cooling fan FAN1.

The heat radiating structure HS1 may include the heat radiating plate BSP1, the side protrusion part ESP1, and the heat radiating fins FIN11 and FIN16. In some exemplary embodiments, the heat radiating plate BSP1, the side protrusion part ESP1, and the heat radiating fins FIN11 and FIN16 may be integrally formed.

The heat radiating plate BSP1 may be in contact with a heat generation object. The heat generation object may correspond to the light sources LS1. The heat radiating plate BSP1 may be in contact with the light sources LS1 through the side protrusion part ESP1. The side protrusion part ESP1 may protrude toward the display panel DP from the heat radiating plate BSP1. When the light sources LS1 are disposed in the directional backlight structure, the side protrusion part ESP1 may be omitted.

The heat radiating fins FIN11 and FIN16 may be located on one surface of the heat radiating plate BSP1, and form sidewalls of a heat radiation path.

The fluid guide ARS1 may be located between the plurality of heat radiating fins FIN11 and FIN16, and have a shape protruding from the heat radiating plate BSP1. In some exemplary embodiments, the fluid guide ARS1 may be a component independent from the heat radiating plate BSP1. In another exemplary embodiment, the fluid guide ARS1 may be integrally formed with the heat radiating plate BSP1.

The fluid guide ARS1 may have a sectional area narrowed when it is distant from the heat radiating plate BSP1, and have a sectional area narrowed when it is close to the cooling fan FAN1. That is, the sectional area decreases with increasing distance away from the heat radiating plate BSP1.

For example, referring to FIG. 4, the fluid guide ARS1 may have a truncated conical shape. The fluid guide ARS1 may include an upper surface UF1, an inclined surface TF1, and a lower surface BF1. The area of the upper surface UF1 may be smaller than that of the lower surface BF1.

For another example, referring to FIG. 5, a fluid guide ARS1′ may have a conical shape. The fluid guide ARS1′ may include an inclined surface TF1′ and a lower surface BF1′.

Hereinafter, for convenience of description, a case where the fluid guide ARS1 has the truncated conical shape is assumed and illustrated.

The position of a rotation axis RAX1 of the cooling fan FAN1 may correspond to the rotation axis RAX1 of the fluid guide ARS1. For example, the position of the rotation axis RAX1 of the cooling fan FAN1 may be arranged to correspond to the center of the fluid guide ARS1. When the fluid guide ARS1 has the truncated conical shape, the center of the fluid guide ARS1 may mean a virtual line connecting the center of the upper surface UF1 and the center of the lower surface BF1. The virtual line may be located on the same line as the rotation axis RAX1. When the fluid guide ARS1′ has the conical shape, the center of the fluid guide ARS1′ may mean a virtual line connecting the vertex of the conical shape and the center of the lower surface BF1′.

When the fluid guide ARS1 does not exist, a cooling fluid supplied from the cooling fan FAN1 may be reflected on the heat radiating plate BSP1 and not supplied to the heat radiation path. When the fluid guide ARS1 exists, the cooling fluid supplied from the cooling fan FAN1 is supplied obliquely to the heat radiating plate BSP1 along the inclined surface TF1. Thus, the cooling fluid can be prevented or reduced from being reflected to the heat radiating plate BSP1. According to the exemplary embodiments, the heat sink decreases the reflection amount of the cooling fluid, so that heat can be effectively radiated or dispersed. Accordingly, the display device 9 can display an image with high luminance.

The duct cover DC1 may form an upper wall and an outlet of the heat radiation path by covering the heat radiating fins FIN11 and FIN16. The duct cover DC1 may include an inlet located corresponding to the cooling fan FAN1.

Another heat sink may refer to an assembly of the heat radiating structure HS2, the fluid guide ARS2, the duct cover DC2, and the cooling fan FAN2, and its overlapping descriptions will be omitted.

The top chassis TPS and the bottom chassis BTS may fix the positions of the other components of the display device 9. The bottom chassis BTS may support the other surfaces of the heat radiating plates BSP1 and BSP2. In some exemplary embodiments, the heat radiating plates BSP1 and BSP2 may be located on the bottom chassis BTS to be spaced apart from each other.

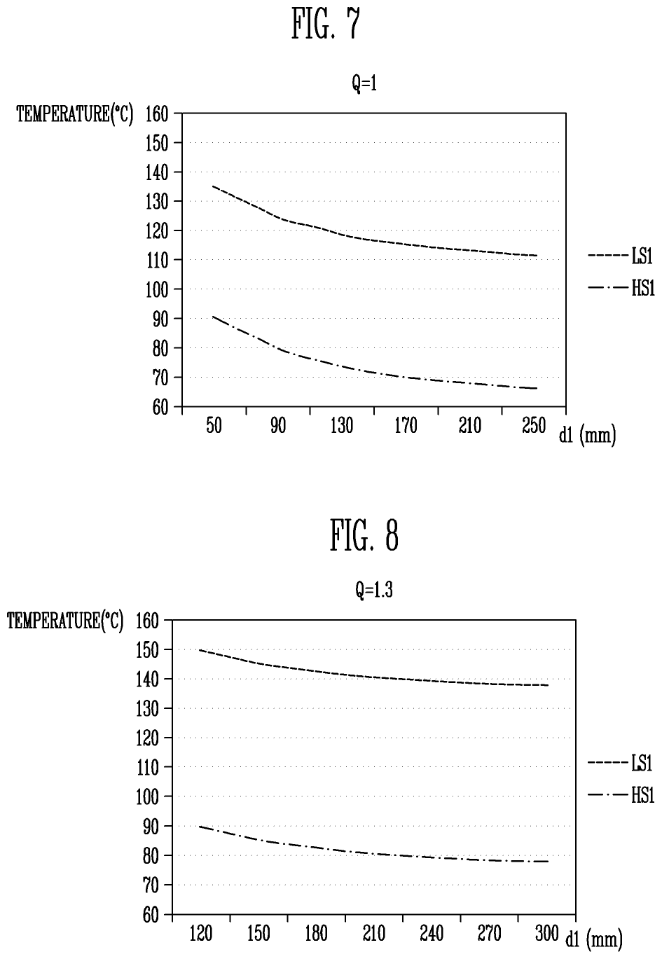

FIGS. 6, 7, and 8 are diagrams illustrating a cooling effect according to the length of a heat radiating plate.

Referring to FIG. 6, according to the edge type backlight structure, light sources LS11, LS12, LS13, LS14, LS15, and LS16 are arranged at a first side S1 in a first direction X. The light sources LS11, LS12, LS13, LS14, LS15, and LS16 correspond to the light sources LS1 of FIG. 3. The length dl of the heat radiating plate BSP1 may correspond to a length of the heat radiating plate BSP1 extending in a second direction Y orthogonal to the first direction X.

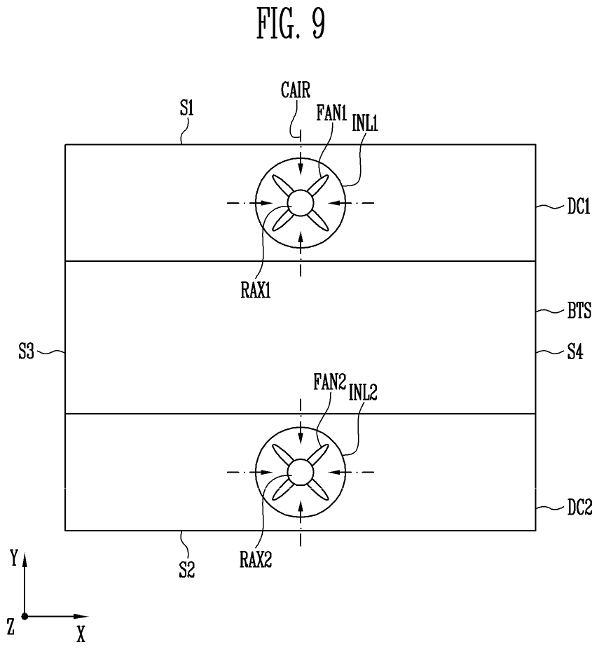

FIG. 7 illustrates, when assuming that the emission amount Q of the light sources LS1 is 1, temperature of the heat radiating structure HS1 and the light sources LS1 depending on the length dl of the heat radiating plate BSP1. Referring to FIGS. 6 and 7, after the length dl of the heat radiating plate BSP1 reaches a certain length, further increase in the length dl of the heat radiating plate BSP1 has insignificant effect on additional cooling effect to lower the temperature of the heat radiating structure HS1 and the light sources LS1.

FIG. 8 illustrates, when assuming that the emission amount Q of the light sources LS1 is 1.3, temperature of the heat radiating structure HS1 and the light sources LS1 depending on the length dl of the heat radiating plate BSP1. Similar to the case of FIG. 7, after the length dl of the heat radiating plate BSP1 reaches a certain length, further increase in the length dl of the heat radiating plate BSP1 has insignificant effect on additional cooling effect to lower the temperature of the heat radiating structure HS1 and the light sources LS1.

Thus, it can be seen that a radiation effect that can be acquired by simply increasing the length dl of the heat radiating plate BSP1 is limited.

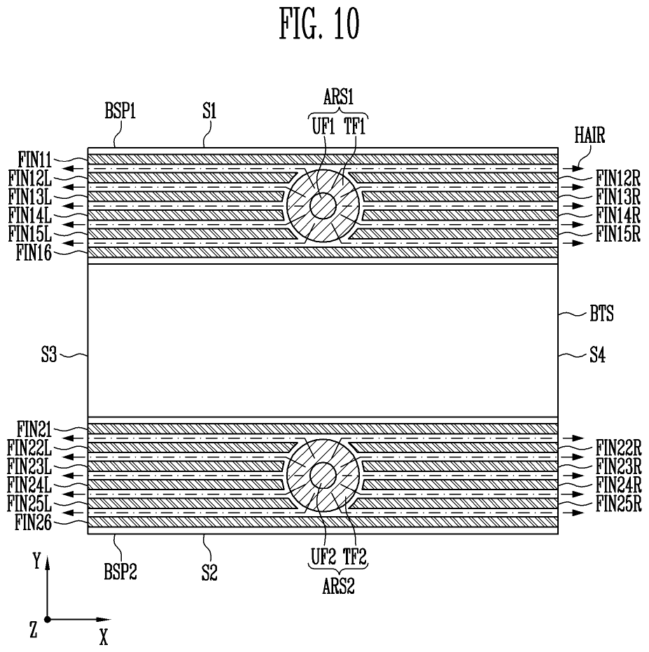

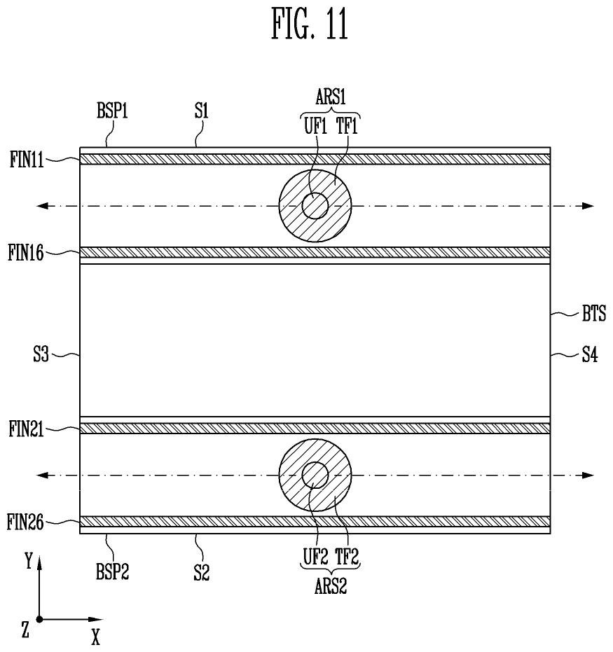

FIGS. 9 and 10 are diagrams illustrating a heat sink according to a first embodiment.

FIG. 9 illustrates the back side of the display device 9, showing the duct covers DC1 and DC2, the bottom chassis BTS, and the cooling fans FAN1 and FAN2.

The duct covers DC1 and DC2 may have inlets INL1 and INL2 located corresponding to the cooling fans FAN1 and FAN2, respectively.

The cooling fans FAN1 and FAN2 may have rotation axes RAX1 and RAX2, respectively. The cooling fans FAN1 and FAN2 are rotated about the rotation axes RAX1 and RAX2, to provide a cooling fluid CAIR to the inlets INL1 and INL2, respectively.

FIG. 10 illustrates the same viewpoint of the back side of the display device 9 as FIG. 9, with the duct covers DC1 and DC2 and the cooling fans FAN1 and FAN2 omitted. Therefore, FIG. 10 illustrates the heat radiating plates BSP1 and BSP2, heat radiating fins FIN11, FIN12L, FIN13L, FIN14L, FIN15L, FIN12R, FIN13R, FIN14R, FIN15R, FIN16 and FIN21 to FIN26, and the fluid guides ARS1 and ARS2.

The heat radiating fins FIN11, FIN12L, FIN13L, FIN14L, FIN15L, FIN12R, FIN13R, FIN14R, FIN15R, and FIN16 may be located on the heat radiating plate BSP1, and form sidewalls of a heat radiation path. Outermost heat radiating fins FIN11 and FIN16 may extend in a first direction X, so that both ends of the outermost heat radiating fins FIN11 and FIN16 are located at a third side S3 and a fourth side S4, respectively.

Internal heat radiating fins FIN12L, FIN13L, FIN14L, and FIN15L extend in the first direction X. One ends of the internal heat radiating fins FIN12L, FIN13L, FIN14L, and FIN15L may be located at the third side S3, and the other ends of the internal heat radiating fins FIN12L, FIN13L, FIN14L, and FIN15L may be located adjacent to the fluid guide ARS1. Lengths of the internal heat radiating fins FIN12L, FIN13L, FIN14L, and FIN15L may be different from each other depending on the shape of the fluid guide ARS1.

Internal heat radiating fins FIN12R, FIN13R, FIN14R, and FIN15R extend in the first direction X. One ends of the internal heat radiating fins FIN12R, FIN13R, FIN14R, and FIN15R may be located adjacent to the fluid guide ARS1, and the other ends of the internal heat radiating fins FIN12R, FIN13R, FIN14R, and FIN15R may be located at the fourth side S4. Lengths of the internal heat radiating fins FIN12R, FIN13R, FIN14R, and FIN15R may be different from each other depending on the shape of the fluid guide ARS1.

The lengths of the internal heat radiating fins located at the opposite sides with respect to the fluid guide ARS1 may be equal to each other. For example, the lengths of the internal heat radiating fins FIN12L and FIN12R may be equal to each other, the lengths of the internal heat radiating fins FIN13L and FIN13R may be equal to each other, the lengths of the internal heat radiating fins FIN14L and FIN14R may be equal to each other, and the lengths of the internal heat radiating fins FIN15L and FIN15R may be equal to each other.

The fluid guide ARS1 may be located between the heat radiating fins FIN11, FIN12L, FIN13L, FIN14L, FIN15L, FIN12R, FIN13R, FIN14R, FIN15R, and FIN16, and have a shape protruding from the heat radiating plate BSP1. The position of the fluid guide ARS1 may correspond to that of the cooling fan FAN1. Thus, the cold cooling fluid CAIR introduced into the inlet INL1 can be introduced into the heat radiation path along the inclined surface TF1 of the fluid guide ARS1. The cooling fluid CAIR absorbs heat of the heat radiating fins FIN11, FIN12L, FIN13L, FIN14L, FIN15L, FIN12R, FIN13R, FIN14R, FIN15R, and FIN16 and the heat radiating plate BSP1 while moving along the heat radiation path, to become a hot cooling fluid. Thus, the hot cooling fluid CAIR can be discharged through the outlet.

Overlapping descriptions of the heat radiating plate BSP2, the heat radiating fins FIN21 to FIN26, and the fluid guide ARS2 will be omitted.

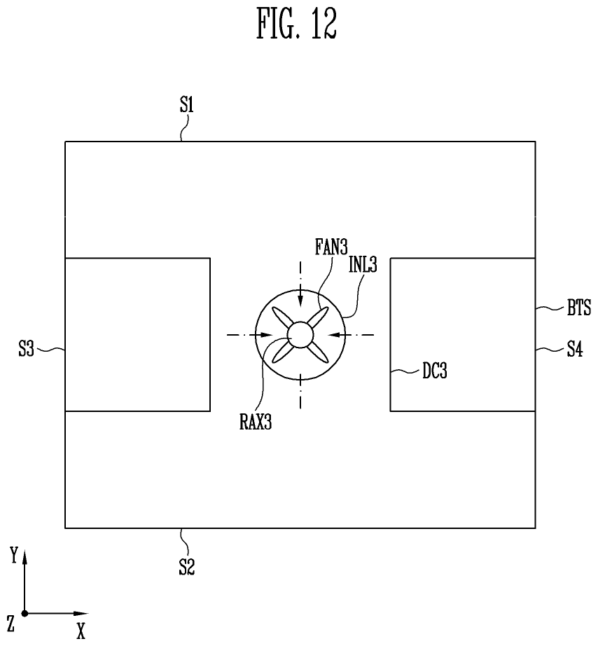

FIG. 11 is a diagram illustrating a heat sink according to a second embodiment.

As compared with FIG. 10, the heat sink of the second embodiment of FIG. 11 is different from the heat sink of the first embodiment of FIG. 10 in that the internal heat radiating fins FIN12L to FIN15L, FIN12R to FIN15R, FIN22L to FIN25L, and FIN22R to FIN25R do not exist.

According to the heat sink of the second embodiment, the flow rate of a cooling fluid can be increased as compared with the heat sink of the first embodiment.

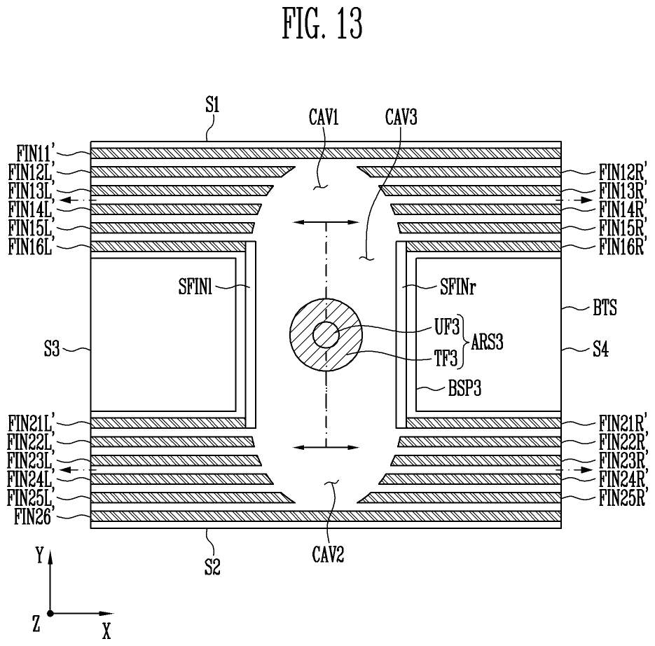

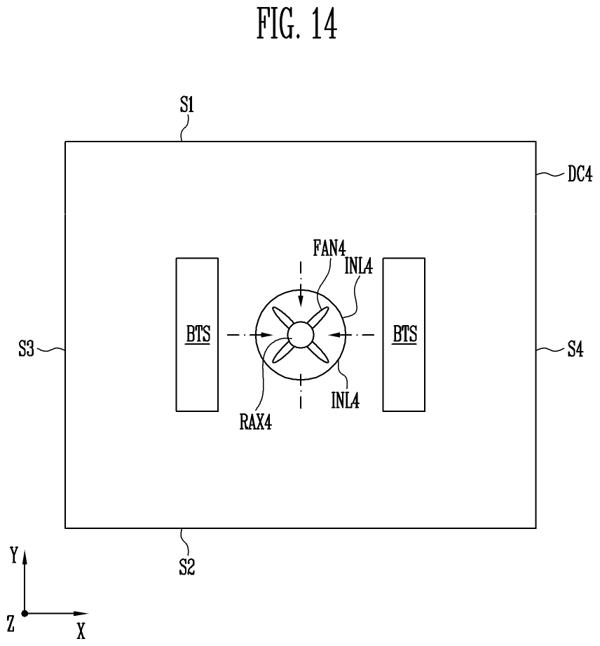

FIGS. 12 and 13 are diagrams illustrating a heat sink according to a third embodiment.

A heat radiating plate BSP3 may be in contact with light sources LS1 of a first group among a plurality of light sources at a first side S1, and be in contact with light source LS2 of a second group among the plurality of light sources at a second side S2 that is a side opposite to the first side S1.

The heat radiating plate BSP3 covers both the first side S1 and the second side S2, at which the light sources LS1 and LS2 are located, and may not cover a portion of a third side S3 and a fourth side S4. Therefore, the heat radiating plate BSP3 may have a bottleneck portion facing from the first side S1 to the second side S2. For example, the heat radiating plate BSP3 may have an ‘H’ shape.

A fluid guide ARS3 may have a shape protruding from one surface of the heat radiating plate BSP3. The fluid guide AR3 may be located in the middle of the first side S1 and the second side S2 of the heat radiating plate BSP3. Also, the fluid guide AR3 may be located in the middle of the third side S3 and the fourth side S4 of the heat radiating plate BSP3. The fluid guide ARS3 may be located at the center of the heat radiating plate BSP3. The fluid guide ARS3 may be located at the bottleneck portion of the heat radiating plate BSP3.

A cooling fan FAN3 may be located to correspond to the position of the fluid guide ARS3.

Heat radiating fins FIN11′, FIN12L′, FIN13L′, FIN14L′, FIN15L′, FIN12R′, FIN13R′, FIN14R′, FIN15R′, FIN16′, FIN21L′, FIN22L′, FIN23L′, FIN24L′, FIN 25L′, FIN21R′, FIN22R′, FIN23R′, FIN24R′, FIN 25R′ and FIN26′ may be located on the one surface of the heat radiating plates BSP3, and form sidewalls of a heat radiation path with respect to the plurality of light sources LS1 and LS2. Outermost heat radiating fins FIN11′ and FIN26′ may extend in a first direction X, so that both ends of the outermost heat radiating fins FIN11′ and FIN26′ are located at a third side S3 and a fourth side S4, respectively.

Internal heat radiating fins FIN12L′, FIN13L′, FIN14L′, FIN15L′, and FIN16L′ extend in the first direction X. One ends of the internal heat radiating fins FIN12L′, FIN13L′, FIN14L′, FIN15L′, and FIN16L′ may be located at the third side S3, and the other ends of the internal heat radiating fins FIN12L′, FIN13L′, FIN14L′, FIN15L′, and FIN16L′ may be located adjacent to a cavity CAV1. In addition, internal heat radiating fins FIN12R′, FIN13R′, FIN14R′, FIN15R′, and FIN16R′ extend in the first direction X. One ends of the internal heat radiating fins FIN12R′, FIN13R′, FIN14R′, FIN15R′, and FIN16R′ may be located adjacent to the cavity CAV1, and the other ends of the internal heat radiating fins FIN12R′, FIN13R′, FIN14R′, FIN15R′, and FIN16R′ may be located at the fourth side S4.

Lengths of the internal heat radiating fins FIN12L′, FIN13L′, FIN14L′, FIN15L′, and FIN16L′ and FIN12R′, FIN13R′, FIN14R′, FIN15R′, and FIN16R′ may be different from each other depending on the shape of the cavity CAV1. In order to form the cavity CAV1 having an arch shape, the lengths of the internal heat radiating fins FIN12L′, FIN13L′, FIN14L′, FIN15L′, and FIN16L′ and FIN12R′ to FIN16′ may be formed long when they are close to the first side S1.

Internal heat radiating fins FIN21L′, FIN22L′, FIN23L′, and FIN24L′, and FIN25L′ extend in the first direction X. One ends of the internal heat radiating fins FIN21L′, FIN22L′, FIN23L′, and FIN24L′, and FIN25L′ may be located at the third side S3, and the other ends of the internal heat radiating fins FIN21L′, FIN22L′, FIN23L′, and FIN24L′, and FIN25L′ may be located adjacent to a cavity CAV2. In addition, internal heat radiating fins FIN21R′, FIN22R′, FIN23R′, FIN24R′, and FIN25R′ extend in the first direction X. One ends of the internal heat radiating fins FIN21R′, FIN22R′, FIN23R′, FIN24R′, and FIN25R′ may be located adjacent to the cavity CAV2, and the other ends of the internal heat radiating fins FIN21R′, FIN22R′, FIN23R′, FIN24R′, and FIN25R′ may be located at the fourth side S4.

Lengths of the internal heat radiating fins FIN21L′, FIN22L′, FIN23L′, FIN24L′, FIN 25L′ and FIN21R′, FIN22R′, FIN23R′, FIN24R′, FIN 25R′ may be different from each other depending on the shape of the cavity CAV2. In order to form the cavity CAV2 having an arch shape, the lengths of the internal heat radiating fins FIN21L′, FIN22L′, FIN23L′, FIN24L′, FIN 25L′ and FIN21R′, FIN22R′, FIN23R′, FIN24R′, FIN 25R′ may be formed long when they are close to the first side S1.

A duct cover DC3 may cover the heat radiating fins FIN11′, FIN12L′, FIN13L′, FIN14L′, FIN15L′, FIN12R′, FIN13R′, FIN14R′, FIN15R′, FIN16′, FIN21L′, FIN22L′, FIN23L′, FIN24L′, FIN 25L′, FIN21R′, FIN22R′, FIN23R′, FIN24R′, FIN 25R′ and FIN26′ and auxiliary fins SFINl and SFINr. The duct cover DC3 covers the plurality of heat radiating fins FIN11′, FIN12L′, FIN13L′, FIN14L′, FIN15L′, FIN12R′, FIN13R′, FIN14R′, FIN15R′, FIN16′, FIN21L′, FIN22L′, FIN23L′, FIN24L′, FIN 25L′, FIN21R′, FIN22R′, FIN23R′, FIN24R′, FIN 25R′ and FIN26′, to form an upper wall and an outlet of the heat radiation path. The duct cover DC3 may include an inlet INL3 located corresponding to the cooling fan FAN3.

The auxiliary fins SFINl and SFINr may be connected to at least some FIN16L′, FIN16R′, FIN21L′, and FIN21R′ of the plurality of heat radiation fins FIN11′, FIN12L′, FIN13L′, FIN14L′, FIN15L′, FIN12R′, FIN13R′, FIN14R′, FIN15R′, FIN16′, FIN21L′, FIN22L′, FIN23L′, FIN24L′, FIN 25L′, FIN21R′, FIN22R′, FIN23R′, FIN24R′, FIN 25R′ and FIN26′, the heat radiation plate BSP3, and the duct cover DC3, to fluidically connect the heat radiation path and the inlet INL3. That is, the auxiliary fins SFINl and SFINr may form a cavity CAV3, and the cavities CAV1, CAV2, and CAV3 may be connected to one another.

The auxiliary fins SFINl and SFINr may be members independent from other components. In another exemplary embodiment, the auxiliary fins SFINl and SFINr may be members extending from at least some FIN16L′, FIN16R′, FIN21L′, and FIN21R′ of the plurality of heat radiation fins FIN11′, FIN12L′, FIN13L′, FIN14L′, FIN15L′, FIN12R′, FIN13R′, FIN14R′, FIN15R′, FIN16′, FIN21L′, FIN22L′, FIN23L′, FIN24L′, FIN 25L′, FIN21R′, FIN22R′, FIN23R′, FIN24R′, FIN 25R′ and FIN26′. In another exemplary embodiment, the auxiliary fins SFINl and SFINr may be members extending from the duct cover DC3. In another exemplary embodiment, the auxiliary fins SFINl and SFINr may be members extending from the heat radiating plate BSP3.

According to the current exemplary embodiment, although one cooling fan FAN3 is used, cooling of the light sources LS1 and LS2 at both the sides S1 and S2 can be performed.

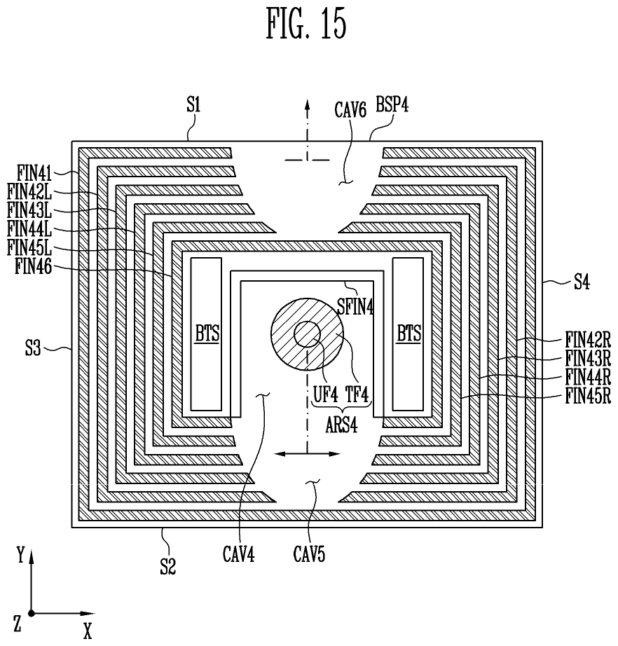

FIGS. 14 and 15 are diagrams illustrating a heat sink according to a fourth embodiment.

A heat radiating plate BSP4 may be in contact with light sources LS1 of a first group among a plurality of light sources at a first side S1, and be in contact with light source LS2 of a second group among the plurality of light sources at a second side S2 that is a side opposite to the first side S1. Also, the heat radiating plate BSP4 may be in contact with light sources LS1 of a third group among the plurality of light sources at a third side S3 connecting the first side S1 and the second side S2, and be in contact with light source LS2 of a fourth group among the plurality of light sources at a fourth side S4 that is a side opposite to the third side S3.

Unlike the case of FIG. 6, the heat sink of the fourth embodiment is an exemplary embodiment in which the light sources are located at all the first to fourth sides S1, S2, S3, and S4.

A fluid guide ARS4 may have a shape protruding from one surface of the heat radiating plate BSP4. The fluid guide ARS4 may be located in the middle of the first side S1 and the second side S2 of the heat radiating plate BSP4. Also, the fluid guide ARS4 may be located in the middle of a third side S3 and a fourth side S4 of the heat radiating plate BSP4. The fluid guide ARS4 may be located at the center of the heat radiating plate BSP4.

A cooling fan FAN4 may be located to correspond to the position of the fluid guide ARS4.

Heat radiating fins FIN41, FIN42L, FIN43L, FIN 44L, FIN 45L, FIN42R, FIN43R, FIN 44R, FIN 45R, and FIN46 may be located on one surface of the heat radiating plate BSP4, and form sidewalls of a heat radiation path with respect to the plurality of light sources.

An outermost heat radiating fin FIN41 may extend to surround the second side S2, the third side S3, and the fourth side S4. Both ends of the outermost heat radiating fin FIN41 may be located at the first side S1, to form an outlet together with a duct cover DC4 and the heat radiating plate BSP4.

An innermost heat radiating fin FIN46 may extend to be parallel to the first side S1, the third side S3, and the fourth side S4. Both end of the innermost heat radiating fin FIN46 may be located adjacent to the second side S2.

One ends of internal heat radiating fins FIN42L, FIN43L, FIN 44L, and FIN 45L may be located adjacent to a cavity CAV5, and the other ends of the internal heat radiating fins FIN42L, FIN43L, FIN 44L, and FIN 45L may be located adjacent to a cavity CAV6. The internal heat radiating fins FIN42L, FIN43L, FIN 44L, and FIN 45L may extend along the first side S1, the third side S3, and the second side S2. The cavity CAV5 may be adjacent to an inlet INL4, and the cavity CAV6 may be adjacent to an outlet.

One ends of internal heat radiating fins FIN42R, FIN43R, FIN 44R, and FIN 45R may be located adjacent to the cavity CAV5, and the other ends of the internal heat radiating fins FIN42R, FIN43R, FIN 44R, and FIN 45R may be located adjacent to the cavity CAV6. The internal heat radiating fins FIN42R, FIN43R, FIN 44R, and FIN 45R may extend along the first side S1, the fourth side S4, and the second side S2.

The duct cover DC4 may cover the heat radiating fins FIN41, FIN42L, FIN43L, FIN 44L, FIN 45L, FIN42R, FIN43R, FIN 44R, FIN 45R, and FIN46 and an auxiliary fin SFIN4. The duct cover DC4 may cover the plurality of heat radiating fins FIN41 to FIN46, to form an upper wall and an outlet of the heat radiation path. The duct cover DC4 may include the inlet INL4 located corresponding to the cooling fan FAN4.

The auxiliary fin SFIN4 may be connected to at least some FIN46 of the plurality of heat radiating fins FIN41, FIN42L, FIN43L, FIN 44L, FIN 45L, FIN42R, FIN43R, FIN 44R, FIN 45R, and FIN46, the heat radiating plate BSP4, and the duct cover DC4, to fluidically connect the heat radiation path and the inlet INL4. The auxiliary fin SFIN4 may form a cavity CAV4, and the cavity CAV4 and the cavity CAV5 may be connected to each other. The cavity CAV5 and the cavity CAVE may be connected to each other through the heat radiation path.

According to the current exemplary embodiment, although one cooling fan FAN4 is used, cooling of the light sources at the four sides S1, S2, S3, and S4 can be performed.

According to the present disclosure, the heat sink can effectively radiate or dissipate heat, and the display device including the heat sink can realize a high-luminance display.

Although certain exemplary embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A heat sink comprising:
a heat radiating plate in contact with a heat generation object;
a plurality of heat radiating fins disposed on the heat radiating plate, the plurality of heat radiating fins forming sidewalls of a heat radiation path;
a fluid guide disposed between the plurality of heat radiating fins, the fluid guide having a shape protruding from the heat radiating plate extending in a first direction; and
a cooling fan having a rotation axis extending in the first direction, the rotation axis of the cooling fan corresponding to the fluid guide.

2. The heat sink of claim 1, wherein the fluid guide has a truncated conical shape in which an area of a first surface opposing the heat radiating plate is smaller than an area of a second surface facing the heat radiating plate.

3. The heat sink of claim 2, wherein a center of the first surface of the fluid guide and a center of the second surface of the fluid guide are located on a rotation axis of the cooling fan.

4. The heat sink of claim 1, wherein the fluid guide has a conical shape.

5. The heat sink of claim 1, wherein the fluid guide has a sectional area and the sectional area decreases with increasing distance away from the heat radiating plate.

6. The heat sink of claim 1, further comprising a duct cover covering the plurality of heat radiating fins, to form an upper wall and an outlet of the heat radiation path,
wherein the duct cover comprises an inlet formed corresponding to the cooling fan.

7. A display device comprising:
a display panel including a plurality of pixels;
a plurality of light sources configured to provide light to the plurality of pixels;
a first heat radiating plate directly contacting a first group of light sources among the plurality of light sources;
a plurality of first heat radiating fins disposed on one surface of the first heat radiating plate, the plurality of first heat radiating fins forming sidewalls of a first heat radiation path;
a first fluid guide disposed between the plurality of first heat radiating fins, the first fluid guide having a shape protruding from the one surface of the first heat radiating plate in a first direction; and
a first cooling fan having a rotation axis extending in the first direction, the rotation axis of the first cooling fan corresponding to the first fluid guide.

8. The display device of claim 7, further comprising:
a second heat radiating plate contacting a second group of light sources among the plurality of light sources;
a plurality of second heat radiating fins disposed on one surface of the second heat radiating plate, the plurality of second heat radiating fins forming sidewalls of a second heat radiation path;
a second fluid guide disposed between the plurality of second heat radiating fins, the second fluid guide having a shape protruding from the one surface of the second heat radiating plate in a second direction; and
a second cooling fan having a rotation axis extending in the second direction, the rotation axis of the second cooling fan corresponding to the second fluid guide.

9. The display device of claim 8, further comprising a bottom chassis supporting a second surface of the first heat radiating plate and a second surface of the second heat radiating plate.

10. The display device of claim 9, wherein the first heat radiating plate and the second heat radiating plate are disposed on the bottom chassis to be spaced apart from each other.

11. A display device comprising:
a display panel including a plurality of pixels;
a plurality of light sources configured to provide light to the plurality of pixels;
a heat radiating plate contacting a first group of light sources among the plurality of light sources at a first side, and contacting a second group of light sources among the plurality of light sources at a second side, the second side being opposite to the first side;
a plurality of heat radiating fins disposed on one surface of the heat radiating plate, the plurality of heat radiating fins forming sidewalls of a heat radiation path with respect to the plurality of light sources;
a fluid guide having a shape protruding from the one surface of the heat radiating plate in a first direction; and
a cooling fan having a rotation axis extending in the first direction, the rotation axis of the cooling fan corresponding to the fluid guide.

12. The display device of claim 11, further comprising a duct cover covering the plurality of heat radiating fins, to form an upper wall and an outlet of the heat radiation path,
wherein the duct cover comprises an inlet formed corresponding to the cooling fan.

13. The display device of claim 12, further comprising an auxiliary fin connected to at least some of the plurality of heat radiating fins, the heat radiating plate, and the duct cover, forming a fluidical connection between the heat radiation path and the inlet.

14. The display device of claim 13, wherein the auxiliary fin extends from at least some of the plurality of heat radiating fins.

15. The display device of claim 13, wherein the auxiliary fin extends from the duct cover.

16. The display device of claim 13, wherein the auxiliary fin extends from the heat radiating plate.

17. The display device of claim 12, wherein the heat radiating plate is contacting a third group of light sources among the plurality of light sources at a third side, the third side connecting the first side and the second side, and
wherein the heat radiating plate is contacting a fourth group of light sources among the plurality of light sources at a fourth side, the fourth side being opposite to the third side.

18. The display device of claim 17, wherein an outermost heat radiating fin of the plurality of heat radiating fins extends to surround the second side, the third side, and the fourth side,
wherein both ends of the outermost heat radiating fin are located at the first side, to form an outlet.
